(19) United States
(12) Patent Application Publication
(10) Pub. No.: US 2018/0033755 A1
(43) Pub. Date: Feb. 1, 2018

(54) INTEGRATED CIRCUIT CHIP AND DISPLAY DEVICE INCLUDING THE SAME

(71) Applicant: Samsung Display Co., Ltd., Yongin-si (KR)

(72) Inventors: Jeong Do YANG, Yongin-si (KR); Jeong Ho HWANG, Cheonan-si (KR); Sang Hyeon SONG, Seoul (KR); Jung Yun JO, Namyangju-si (KR); Seung-Hwa HA, Hwaseong-si (KR)

(21) Appl. No.: 15/656,849

(22) Filed: Jul. 21, 2017

(30) Foreign Application Priority Data
Jul. 29, 2016 (KR) 10-2016-0097038

(51) Int. Cl. H01L 23/00

(52) U.S. Cl. CPC H01L 24/13; H01L 24/05; H01L 24/16; H01L 2224/13026; H01L 2224/13013; H01L 2224/13017; H01L 2224/13023; H01L 2924/1426; H01L 2924/14; H01L 2924/3512; H01L 2224/16227; H01L 2224/16145; H01L 2224/05124; H01L 2224/05144; H01L 2224/05166; H01L 2224/05082; H01L 2224/05013; H01L 2224/0401; H01L 24/03; H01L 24/11; H01L 2224/03622; H01L 2224/1145; H01L 2224/1146

(57) ABSTRACT

An exemplary embodiment provides a driving circuit chip including: a substrate; a terminal electrode disposed on the substrate; and an electrode pad disposed on the terminal electrode, wherein the electrode pad includes: a bump structure protruded from the substrate to include a short side and a long side; and a bump electrode disposed on the bump structure and connected with the terminal electrode around a short edge portion of the bump structure, wherein the bump electrode is disposed to not cover at least a part of a long edge portion of the bump structure.

### CROSS-REFERENCE TO RELATED APPLICATION

This application claims priority to and the benefit of Korean Patent Application No. 10-2016-0097038 filed in the Korean Intellectual Property Office on Jul. 29, 2016, the entire contents of which are incorporated herein by reference.

### BACKGROUND

### (a) Technical Field

This disclosure relates to an integrated circuit chip and a display device including the same.

### (b) Description of the Related Art

Display devices such as an organic light emitting device and a liquid crystal display include a display panel in which pixels for displaying an image are disposed. A pad portion for inputting or outputting signals is provided in the display panel to control an operation of the display panel, and an integrated circuit chip or a flexible printed circuit in which the integrated circuit chip is mounted is bonded in the pad portion.

An anisotropic conductive layer (ACF) is used for electrically and physically connecting the connection member and the pad portion. The anisotropic conductive layer as a film in which conductive particles are arranged on an insulating layer made of a resin material and the like has conductivity in a thickness direction thereof and has an insulation property in a surface direction.

The anisotropic conductive layer includes the conductive particles, and the conductive particles are positioned between a pad of the pad portion and a bump of the connection member while contacting them to electrically connect them. Further, as the resolution of the display device is increased, a size of the conductive particles is decreased, and the number of conductive particles is required to be increased in order to suppress an increase in resistance between pads and bumps. However, increasing the number of conductive particles may lead to short-circuit errors caused by aggregation of the conductive particles. Further, resistance deviation may be increased depending on the number of conductive particles positioned between the pads and the bumps.

The above information disclosed in this Background section is only for enhancement of understanding of the background and therefore it may contain information that does not form the prior art that is already known in this country to a person of ordinary skill in the art.

### SUMMARY

Exemplary embodiments have been made in an effort to provide an integrated circuit chip and a display device including the same, capable of improving reliability.

An exemplary embodiment provides a driving circuit chip including: a substrate; a terminal electrode disposed on the substrate; and an electrode pad disposed on the terminal electrode, wherein the electrode pad includes: a bump structure protruded from the substrate to include a short side and a long side; and a bump electrode disposed on the bump structure and connected with the terminal electrode around a short edge portion of the bump structure, wherein the bump electrode is disposed to not cover at least a part of a long edge portion of the bump structure.

The bump electrode may be disposed to not cover the long edge portion that is adjacent to the short edge portion of the bump structure.

The bump structure may have a planar shape that is substantially rectangular and a short-side directional cross-section that is substantially semi-circular.

The integrated circuit chip may further include an insulating layer disposed between the terminal electrode and the electrode pad, and the bump structure may not contact the terminal electrode.

The bump electrode may have a portion that contacts the insulating layer at opposite sides of the bump structure in a long-side direction of the bump structure.

The integrated circuit chip may further include an insulating layer disposed between the terminal electrode and the electrode pad, and the bump structure may contact the terminal electrode.

The bump electrode may have a portion that contacts the terminal electrode at opposite sides of the bump structure in a long-side direction of the bump structure.

The bump structure may be integrally disposed with the insulating layer. The bump structure may be overlapped with the terminal electrode, and a planar surface area of the terminal electrode may be wider than that of the bump structure.

The bump electrode may be disposed to not entirely cover the long edge portion of the bump structure.

An exemplary embodiment provides a display device including: a display panel including a pad portion; and an integrated circuit chip bonded to the pad portion.

According to the exemplary embodiments, it is possible to prevent crack generation by reducing a stress applied to the edge portion of the bump electrode of the driving circuit chip, and it is possible to prevent a crack which may be generated in the long edge portion from being expanded in the short-side direction. Accordingly, it is possible to improve connection reliability of the driving circuit chip.

### BRIEF DESCRIPTION OF THE DRAWINGS

FIG. 1 is a top plan view schematically illustrating a display device according to an exemplary embodiment.

FIG. 2 is a top plan view schematically illustrating a driving circuit chip in the display device shown in FIG. 1.

FIG. 3 is a perspective view illustrating one electrode pad of a driving circuit chip according to an exemplary embodiment.

FIG. 4 is a top plan view of an electrode pad shown in FIG. 3.

FIG. 5 illustrates cross-sectional views taken along lines A-B, B-C, and C-D of FIG. 4 according to an exemplary embodiment.

FIG. 6 illustrates a cross-sectional view taken along a line E-F of FIG. 4 according to an exemplary embodiment.

FIG. 7 illustrates cross-sectional views taken along lines A-B, B-C, and C-D of FIG. 4 according to an exemplary embodiment.

FIG. 8 illustrates cross-sectional views taken along lines A-B, B-C, and C-D of FIG. 4 according to an exemplary embodiment.

FIG. 9 is a top plan view illustrating a mask used to form an electrode pad according to an exemplary embodiment.

FIG. 10 is a perspective view illustrating one electrode pad of a driving circuit chip according to an exemplary embodiment.

FIG. 11 is a perspective view illustrating one electrode pad of a driving circuit chip according to an exemplary embodiment.

FIG. 12 illustrates a stress simulation result of an electrode pad according to an example.

FIG. 13 illustrates a stress simulation result of an electrode pad according to a comparative example.

FIG. 14 is a cross-sectional view corresponding to one electrode pad and one pad region in the display device of FIG. 1.

### DETAILED DESCRIPTION OF THE EMBODIMENTS

The inventive concept will be described more fully hereinafter with reference to the accompanying drawings, in which exemplary embodiments of the inventive concept are shown. As those skilled in the art would realize, the described embodiments may be modified in various different ways, all without departing from the spirit or scope of the inventive concept.

To clearly describe the embodiments, parts that are irrelevant to the description are omitted, and like numerals refer to like or similar constituent elements throughout the specification.

In the drawings, the size and thickness of each element are arbitrarily illustrated for ease of description, and the present disclosure is not necessarily limited to those illustrated in the drawings. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or above the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means viewing a target portion from the top, and the phrase “in a cross-sectional view” means viewing a cross-section formed by vertically cutting a target portion from the side

A display device according to an exemplary embodiment will now be described in detail with reference to the accompanying drawings.

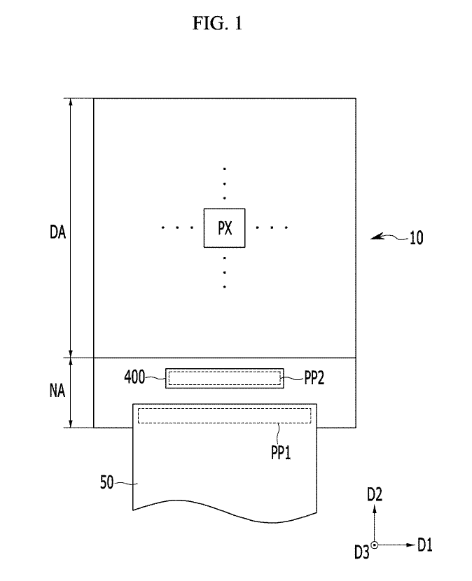

FIG. 1 is a top plan view schematically illustrating a display device according to an exemplary embodiment.

Referring to FIG. 1, the display device according to an exemplary embodiment includes a display panel 10 and a flexible printed circuit 50 connected with the display panel 10. The display panel 10 may be an organic light emitting device panel or a liquid crystal panel, but is not limited thereto.

The display panel 10 includes a display area DA for displaying an image, and a non-display area NA outside the display area DA in which elements and wires for generating and/or transmitting various signals applied to the display area DA and/or wiring are disposed. In FIG. 1, although only one side edge region (e.g., a lower region) of the display panel 10 is shown as the non-display area NA, the other side edge regions (e.g., left and right edges and/or an upper edge) of the display panel 10 may be the non-display area NA. The display area DA is shown to be quadrangular, but it may be circular, oval, or polygonal.

Pixels PX are disposed, for example, in a matrix in the display area DA of the display panel 10. Further, signal lines such as gate lines (not shown), data lines (not shown), and the like are disposed in the display area DA. The gate lines substantially extend in a first direction D1 (e.g., a row direction), and the data lines substantially extend in a second direction D2 (e.g., a column direction) crossing the first direction D1. Each pixel PX may be connected to a gate line and a data line to receive a gate signal and a data signal from these lines. In the case of an organic light emitting device, driving voltage lines (not shown), which substantially extend, for example, in the second direction D2 to transmit a driving voltage to the pixels PX, may be disposed in the display area DA.

A pad portion PP1 for receiving an external signal is disposed in the non-display area NA of the display panel 10. One end of the flexible printed circuit 50 is connected to the pad portion PP1. The other end of the flexible printed circuit 50 may be connected to, for example, an external printed circuit board (PCB) to transmit a signal such as an image data signal or a control signal thereto.

A driver for generating and/or processing various signals for driving the display panel 10 may be disposed in the non-display area NA of the display panel 10, the flexible printed circuit 50, or the external printed circuit board (PCB). The driver may include a data driver for applying a data signal to the data line, a gate driver for applying a gate signal to the gate line, and a signal controller for controlling the data driver and the gate driver.

In the shown exemplary embodiment, the data driver as a form of an integrated circuit chip 400 is mounted on a pad portion PP2 disposed between the display area DA and the pad portion PP1. A non-conductive film (NCF) (not illustrated) including an adhesive may be disposed between the pad portion PP2 and the integrated circuit chip 400 to bond the integrated circuit chip 400 to the pad portion PP2. In this case, electrode pads (not illustrated) of the integrated circuit chip 400 contact the pads (not illustrated) of the pad portion PP2 and are electrically connected thereto. Unlike as illustrated, the data driver may be mounted on the flexible printed circuit 50 in a form of the integrated circuit chip to be connected to the pad portion PP1 in a form of a tape carrier package (TCP). The gate driver may be integrated in the non-display area (not shown) of left and/or right edges of the display panel 10, or may be provided as an integrated circuit chip. The signal controller may be formed as the integrated circuit chip 400 such as the data driver, or may be provided as a separate integrated circuit chip.

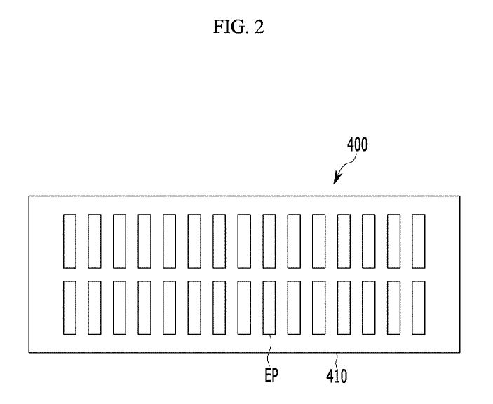

The overall configuration of the display device has been described. Hereinafter, the driving circuit chip 400 bonded to the pad portion PP2 will be described in detail with reference to FIG. 2 to FIG. 6. FIG. 1 may also be referred to describe a relationship with the display panel 10, and all the drawings previously referred to may be re-referred to without any special description.

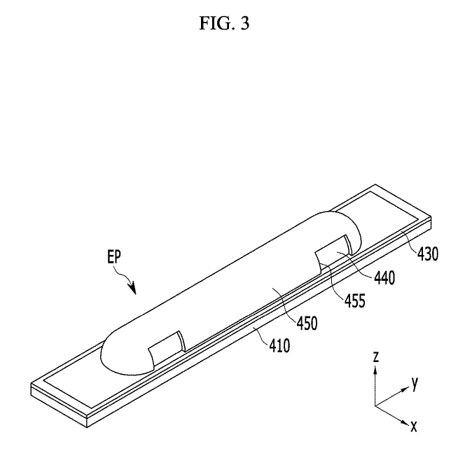

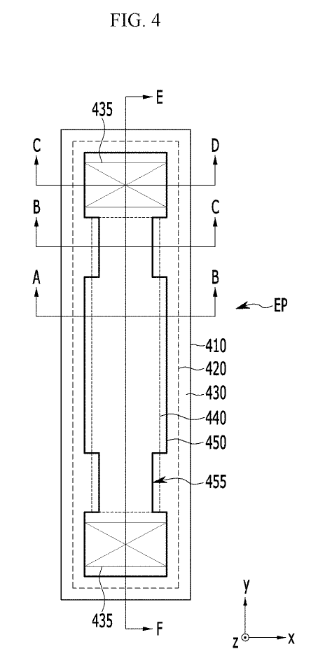

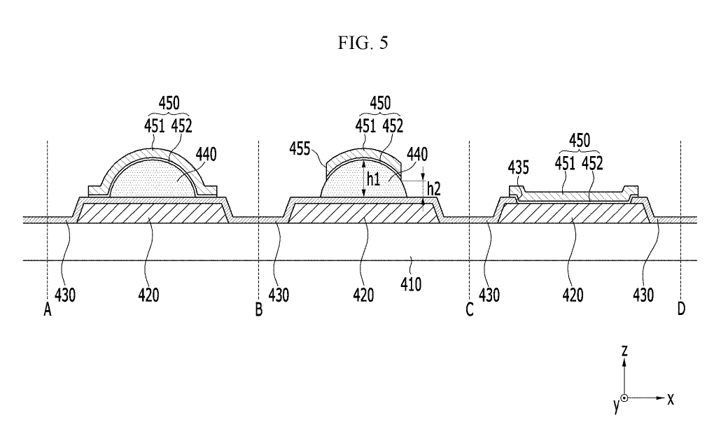

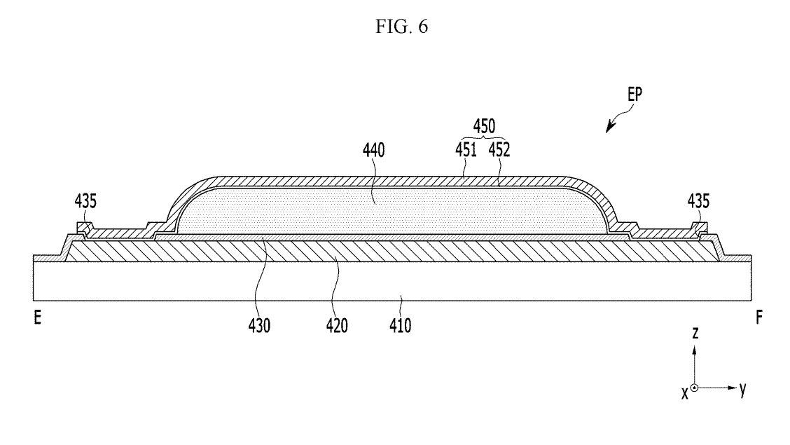

FIG. 2 is a top plan view schematically illustrating a driving circuit chip in the display device shown in FIG. 1, FIG. 3 is a perspective view illustrating one electrode pad of a driving circuit chip according to an exemplary embodiment, FIG. 4 is a top plan view of an electrode pad shown in FIG. 3, FIG. 5 illustrates cross-sectional views taken along lines A-B, B-C, and C-D of FIG. 4 according to an exemplary embodiment, and FIG. 6 illustrates a cross-sectional view taken along a line E-F of FIG. 4 according to an exemplary embodiment.

Referring to FIG. 2, the driving circuit chip 400 includes a substrate 410 and electrode pads EP disposed on the substrate 410. The electrode pads EP are independently formed. Each of the electrode pads EP has a planar shape that is substantially rectangular. Each electrode pad EP has long sides and short sides, and a long-side direction of the electrode pads EP attached to the display panel 10 may be substantially parallel with the second direction D2. Unlike the shown exemplary embodiment, each of the electrode pads EP may have another planar shape such as a parallelogram, and a long-side direction may be inclined to some degree with respect to the second direction D2. In each of the electrode pads EP, the long sides may be substantially the same as the short sides, and the planar shape may be modified in various ways.

A detailed structure of each electrode pad EP will be described with reference to FIG. 3 to FIG. 6. Each of the electrode pads EP includes a bump structure 440 protruded from the substrate 410, and a bump electrode 450 formed to surround the bump structure 440 while upwardly contacting the bump structure 440 but exposing a corner of the bump structure 440. A terminal electrode 420 and a protection layer 430 are disposed between the substrate 410 and the electrode pads EP.

The substrate 410 may be a silicon substrate formed from a wafer. The terminal electrode 420 may be an output electrode or an input electrode of the integrated circuit. The terminal electrode 420 may be formed of a metal such as aluminum (Al), titanium (Ti), gold (Au), tungsten (W), copper (Cu), silver (Ag), and a metal alloy thereof. The terminal electrode 420 may be formed as a single layer or a multi-layer. For example, the terminal electrode 420 may be formed as a single layer including aluminum, and may be formed as a double layer including a lower layer including titanium and an upper layer including gold. The terminal electrode 420 may have a planar shape that is substantially rectangular including short sides and long sides.

The protection layer 430 disposed on the terminal electrode 420 may include an inorganic insulating material such as a silicon nitride (SiNx) or a silicon oxide (SiOx). The protection layer 430 may be formed to entirely cover the substrate 410 and the terminal electrode 420 except for a contact hole 435 contacted by the bump electrode 450.

The bump structures 440 of the electrode pads EP are disposed on the protection layer 430. The bump structures 440 are protruded from the substrate 410 at a predetermined height. Each of the bump structures 440 may have a planar shape that is substantially rectangular including short sides and long sides as shown in FIG. 4 by dotted lines. The bump structures 440 may have a short-side (x) directional cross-section that is substantially semi-circular as shown in FIG. 5, and may have a long-side (y) directional cross-section that is substantially trapezoidal as shown in FIG. 6. Accordingly, each bump structure 440 may have a similar shape to a tunnel, but is not limited thereto. The bump structure 440 may have various 3D shapes. The bump structure 440 is independently formed for each of electrode pads EP.

The bump structure 440 may have a curved surface except for a lower surface that contacts the protection layer 430. In this specification, a portion of the curved surface of the bump structure 440 is referred to as an edge portion. Accordingly, the bump structure 440 includes two edge portions (hereinafter referred to as short edge portions) that are parallel with the short-side (x) direction and two edge portions (hereinafter referred to as long edge portions) that are parallel with the long-side (y) direction.

The bump structure 440 may be formed of an organic material or an inorganic material having appropriate elastic modulus, elastic deformation, and resiliency, and may include a polymer such as a resin. The bump structure 440 may include a conductive polymer.

The bump electrode 450 may be disposed on the bump structure 440. When the integrated circuit chip 400 is bonded to the pad portion PP2 of the display panel 10, the bump electrode 450 contacts pads of the pad portion PP2 to electrically connect the integrated circuit chip 400 to the display panel 10. The bump electrode 450 is connected with the terminal electrode 420 through contact holes 435 formed in the protection layer 430 which is disposed at opposite sides of the bump structure 440 in the long-side (y) direction (accordingly, adjacent to the short edge portion of the bump structure 440). The number and position of the contact hole 435 may be variously changed.

The bump electrode 450 may be a multi-layer including a seed layer 452 and a metal layer 451. The seed layer 452 serves as a base layer for growing the bump electrode 450 by, e.g., plating such as electroplating or electroless plating. The seed layer 452 may include a metal such as titanium, tungsten, chromium, and gold, and the metal layer 451 may include a metal such as gold, copper, silver, platinum, palladium, nickel, and aluminum. Unlike the shown exemplary embodiment, the bump electrode 450 may be a single layer, and may be formed by depositing a metal on the bump structure 440 by sputtering.

The bump electrode 450 entirely covers the bump structure 440 by surrounding the bump structure 440. The bump electrode 450 may be formed to be generally wider than the bump structure 440, and an edge portion of the bump electrode 450 that is not overlapped with the bump structure 440 may contact the protection layer 430 except for a portion that contacts the terminal electrode 420. For example, as shown in a left side of FIG. 5, an edge portion of the bump electrode 450 in the long-side (y) direction may contact the protection layer 430. As such, when the bump electrode 450 is formed to contact the protection layer 430 while covering the bump structure 440, it is possible to prevent the bump electrode 450 from being pulled out or coming off. For example, when the integrated circuit chip 400 is manufactured, a back grinding process of grinding a rear surface of the substrate 410 in a state in which the integrated circuit chip 400 is fixed by attaching the electrode pads EP to an adhesive tape may be performed in order to reduce a thickness of the substrate 410. While the adhesive tape is peeled off after the rear surface of the substrate 410 is ground, the bump electrode 450 may be separated by adhesiveness of the adhesive tape. According to the present exemplary embodiment, as the edge portion of the bump electrode 450 is formed to contact the protection layer 430 in the short-side (x) direction as well as in the long-side (y) direction, fixing power (attachment strength) of the bump electrode 450 may be increased to prevent the bump electrode 450 from being separated from the protection layer 430.

The bump electrode 450 entirely covers the bump structure 440, but does not cover a portion of an external circumferential surface of the bump structure 440, particularly, the long edge portion of the bump structure 440 that is adjacent to the short edge portion of the bump structure 440. Accordingly, the bump electrode 450 has openings 455 for exposing the long edge portion of the bump structure 440. A height h2 of the openings 455 from a surface of the protection layer 430 may be substantially ⅔ or less, ½ or less, or ⅓ or less as compared with a height h1 of the bump structure 440, but the embodiments are not limited thereto. The height h2 may be variously designed.

The integrated circuit chip 400 is compressed in an operation in which the integrated circuit chip 400 is bonded to the pad portion PP2 of the display panel 10. In this case, the bump structure 440 is pushed and expanded by elasticity in a lateral direction (e.g., in a direction that crosses the pushing direction), and the bump electrode 450 surrounding the bump structure 440 is also expanded in the lateral direction. By a 3D shape of the bump structure 440, a stress caused by expansion of a first portion of the bump electrode 450 which is positioned around the long edge portion of the bump structure 440 (hereinafter referred to as a long edge portion of the bump electrode 450) is stronger than that of a second portion thereof which is positioned around the short edge portion of the bump structure 440 (hereinafter referred to as a short edge portion of the bump electrode 450). Accordingly, the short edge portion of the bump electrode 450 is more easily cracked or burst than the short edge portion of the bump electrode 450.

The crack generated at a part of the long edge portion of the bump electrode 450 may be expanded to the short edge portion without being confined to the part. When the crack is expanded to the short edge portion, a connection between the bump electrode 450 and the terminal electrode 420 may be cut off, or resistance therein may be increased. According to the present exemplary embodiment, the openings 455 of the bump electrode 450 are formed at the long edge portion of the bump electrode 450 that is adjacent to the short edge portion thereof, and thus it is possible to block the crack from being expanded from the long edge portion to the short edge portion. Further, it is possible to maintain the fixing power by the long edge portion which contacts the protection layer 430 by forming the opening 455 at a portion that is adjacent to the short edge portion instead of entirely forming the opening 455 at the long edge portion. Meanwhile, when the bump structure 440 is gradually formed, e.g., the long edge portion of the bump structure 440 is formed at a lower height, the crack generation may be reduced at the long edge portion of the bump electrode 450.

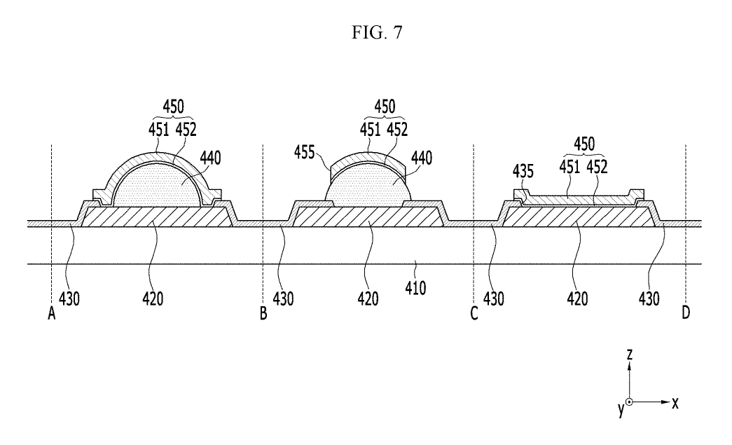

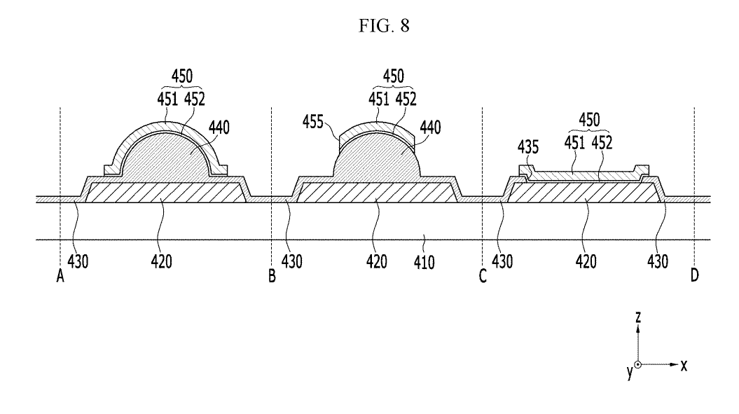

Hereinafter, electrode pads EP according to some other exemplary embodiments will be described based on differences thereof from the aforementioned exemplary embodiment with reference to FIG. 7 and FIG. 8.

FIG. 7 and FIG. 8 illustrate cross-sectional views taken along lines A-B, B-C, and C-D of FIG. 4 according to an exemplary embodiment.

Referring to FIG. 7, in the present exemplary embodiment, the protection layer 430 is not disposed between the terminal electrode 420 and the bump structure 440 unlike in the aforementioned exemplary embodiments of FIG. 3 to FIG. 6 in which the protection layer 430 covers the terminal electrode 420 except for the contact hole 435. Accordingly, a lower surface of the bump structure 440 contacts the terminal electrode 420. The protection layer 430 is not disposed in a region in which the long edge portion of the bump electrode 450 is overlapped with the terminal electrode 420. As a result, the long edge portion of the bump electrode 450 contacts the terminal electrode 420.

According to the present exemplary embodiment, as an area of the bump electrode 450 contacting the terminal electrode 420 is increased, contact resistance may be ameliorated. As in the aforementioned exemplary embodiment, the openings 455 are formed at a portion that is adjacent to the short edge portion to block the crack generated at the long edge portion of the bump electrode 450 from being expanded to the short edge portion. Further, it is possible to maintain the separation strength by the long edge portion of the bump electrode 450 contacting the terminal electrode 420.

Referring to FIG. 8, in the present exemplary embodiment, the protection layer 430 and the bump structure 440 are integrally formed and are integral, unlike in the aforementioned exemplary embodiments of FIG. 3 to FIG. 6 in which the protection layer 430 and the bump structure 440 are separately formed. Specifically, the protection layer 430 and the bump structure 440 may be formed of the same material without layer division. For example, the protection layer 430 and the bump structure 440 may be formed by making a region corresponding to the protection layer 430 relatively thinner through photolithography by thickly coating an organic material such as a photoresist on the substrate 410 and the terminal electrode 420 and using a two-tone mask such as a slit mask or a halftone mask. An example of the employed organic material may include a polymer material such as a polyimide-based material, a polybenzoxazole-based material, an acryl-based material, a phenol-based material, a silicon-based material, a silicon-modified polyimide-based material, an epoxy-based material, or the like. The protection layer 430 and the bump structure 440 may be cured by applying heat or irradiating UV. In this case, a surface of the bump structure 440 may be curvedly formed.

According to the present exemplary embodiment, the protection layer 430 and the bump structure 440 may be formed together by using one mask, thereby reducing processes and accomplishing cost efficiency. As in the aforementioned exemplary embodiment, the openings 455 may be opened at a portion that is adjacent to the short edge portion of the bump electrode 450, and it is possible to maintain the separation strength by the long edge portion of the bump electrode 450 contacting the protection layer 430.

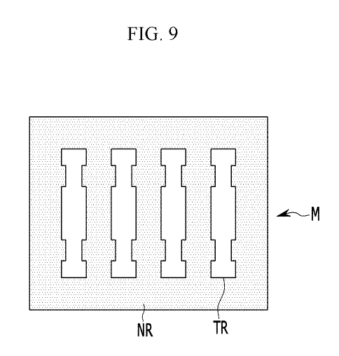

FIG. 9 is a top plan view illustrating a mask used to form an electrode pad according to an exemplary embodiment.

The mask M shown in FIG. 9 may be used to form the bump electrode 450 having the openings 455 by plating as in the aforementioned exemplary embodiments. For example, when the bump electrode 450 is formed by using a positive photoresist, the mask M includes transmissive regions TR corresponding to a planar shape of the bump electrode 450 shown in FIG. 4. The transmissive regions TR are disposed at distances corresponding to distances of the electrode pads EP to be formed. Non-transmissive regions NR are positioned to surround the transmissive regions TR. Accordingly, it is possible to form the bump electrode 450 having the openings 455 at the long edge portion that is adjacent to the short edge portion by removing a photoresist corresponding to the shape of the bump electrode 450 and growing the bump electrode 450 (specifically, the metal layer 451 disposed on the seed layer 452). When a negative photoresist is employed, positions of the transmissive regions TR and the non-transmissive regions NR of the mask M are opposite to each other.

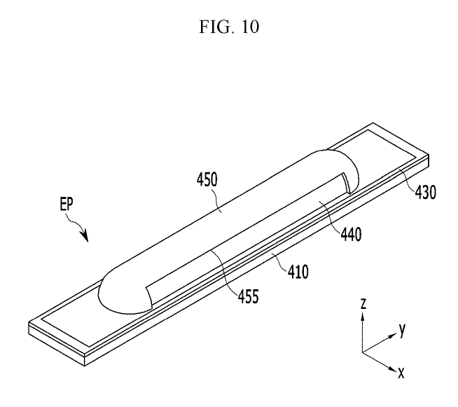

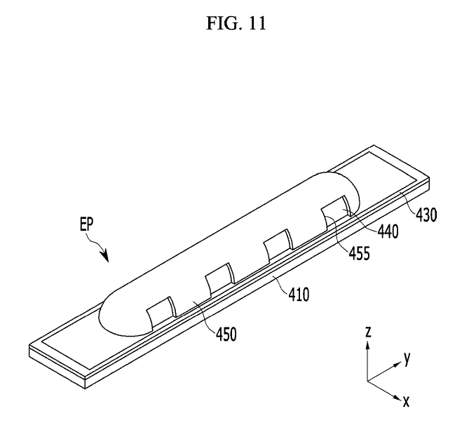

FIG. 10 and FIG. 11 are perspective views illustrating one electrode pad of a driving circuit chip according to an exemplary embodiment.

Referring to FIG. 10, the openings 455 are entirely formed at the long edge portion of the bump electrode 450. In the exemplary embodiment of FIG. 3, the openings 455 are formed at opposite ends of the long edge portion of the bump electrode 450. However, in the present exemplary embodiment, the openings 455 are connected to constitute one opening 455. In this case, the long edge portion of the bump electrode 450 does not contact the protection layer 430 or the terminal electrode 420, and thus the separation strength may be deteriorated, but the long edge portion may be prevented from being cracked or burst.

Referring to FIG. 11, the openings 455 are separately formed at the long edge portion of the bump electrode 450. Compared with the exemplary embodiment of FIG. 3, at least one opening 455 is formed between the openings 455 formed at opposite ends of the long edge portion of the bump electrode 450. In this case, it is possible to maintain fixing power while reducing a region of the long edge portion of the bump electrode 450 that may be cracked.

The exemplary embodiments of FIG. 10 and FIG. 11 are the same as the aforementioned exemplary embodiments in that the bump electrode 450 does not cover the long edge portion that is adjacent to the short edge portion of the bump structure 440. Accordingly, it is possible to prevent crack expansion to the short edge portion.

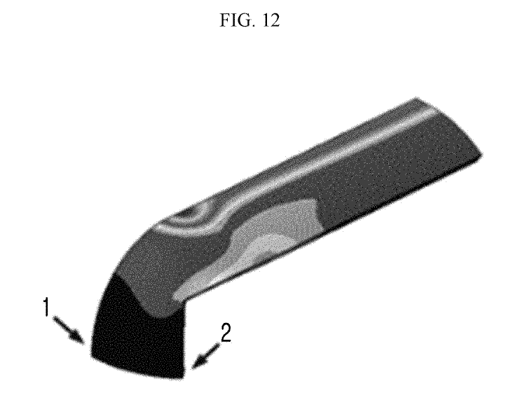

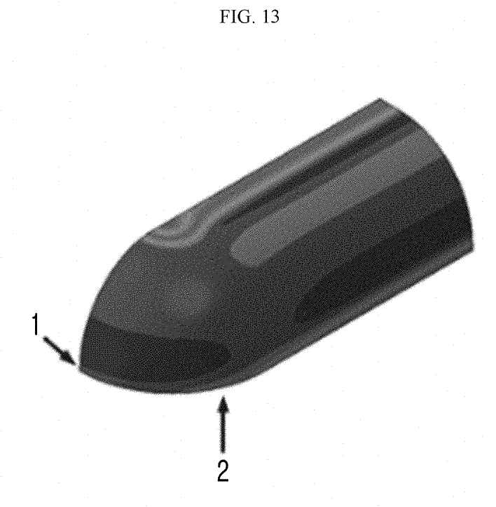

FIG. 12 illustrates a stress simulation result of an electrode pad according to an example, and FIG. 13 illustrates a stress simulation result of an electrode pad according to a comparative example.

FIG. 12 illustrates the case in which the bump electrode 450 is formed to not cover the long edge portion that is adjacent to the short edge portion of the bump structure 440 as in the exemplary embodiments, and FIG. 13 illustrates the case in which the bump electrode 450 is formed to completely cover the long edge portion of the bump structure 440 (i.e., the bump electrode 450 has no opening). In the case of an analytic model shape, a radius of the bump structure 440 is 3 μm, and a thickness of the bump electrode 450 is 700 nm. When a predetermined pressure is applied to the bump electrode 450, stresses were respectively measured at a point 1 which is a short-side center of the bump electrode 450 and a point 2 which is a long-side end as 1360 and 3630 MPa in the comparative example of FIG. 13. However, stresses respectively measured at the point 1 and the point 2 were respectively reduced to 1020 and 653 MPa in the example of FIG. 12. Accordingly, according to an exemplary embodiment, the stress is reduced at a short side of the bump electrode 450, and thus it is possible to reduce crack generation possibility.

The integrated circuit chip 400 has been described. Hereinafter, a state in which the integrated circuit chip 400 is bonded to the pad portion PP2 of the display panel 10 will be described.

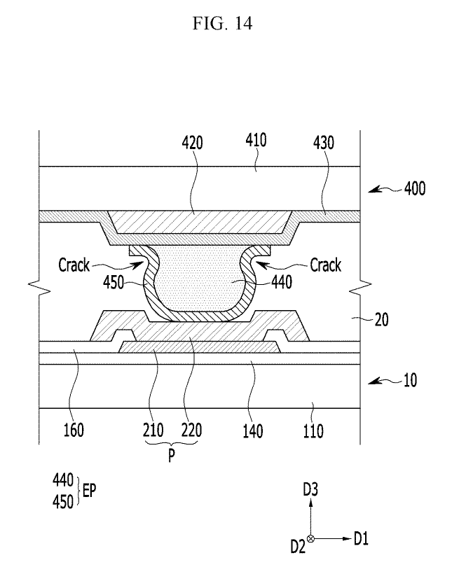

FIG. 14 is a cross-sectional view corresponding to one electrode pad and one pad region in the display device of FIG. 1.

Electrode pads EP bonded to the pad portion PP2 bonded to the display panel 10 will be described by using the electrode pads EP as an example.

The pad portion PP2 includes pads P. The pads P may be arranged in, e.g., the first direction D1 at a predetermined interval, and may be arranged in a single row or in a plurality of rows.

The pads P are disposed on the substrate 110 formed of glass or plastic, and each of the pads P includes a first pad electrode 210 and a second pad electrode 220. A first end of the first pad electrode 210 may be connected with a signal line, such as a data line, of the display panel 10. A protection layer 140 is disposed between the substrate 110 and the pads P. The protection layer 140 may be a barrier layer for preventing moisture penetration, a buffer layer, a gate insulating layer for insulating a semiconductor and a gate electrode, or a multilayer in which they are stacked. An interlayer insulating layer 160 is disposed between the first pad electrode 210 and the second pad electrode 220. The second pad electrode 220 is connected with the first pad electrode 210 through a contact hole formed in the interlayer insulating layer 160.

The electrode pads EP are disposed to overlap the pads P, and are downwardly protruded from the substrate 410 toward the pads P. The bump electrode 450 contacts the second pad electrode 220 corresponding to an upper layer of each of the pads P to electrically connect the terminal electrode 420 of the integrated circuit chip 400 to the pads P of the display panel 10. Accordingly, a signal outputted from the terminal electrode 420 of the integrated circuit chip 400 may be transferred to the signal line of the display panel 10 through the bump electrode 450 and the pad P, and vice versa.

Most space between the integrated circuit chip 400 and the pad portion PP2 is filled with a non-conductive adhesive layer 20, and thus the integrated circuit chip 400 is bonded to the pad portion PP2 by the adhesive layer 20. The integrated circuit chip 400 may be bonded to the bump structure 440, and may be bonded to the pad portion PP2 in a state in which the bump electrode 450 is slightly compressed. In this case, for example, after a time has elapsed after bonding, even when a gap between the integrated circuit chip 400 and the pad portion PP2 is increased, it is possible to maintain the contact between the bump electrode 450 and the pad P by an elastic restoring force of the bump structure 440. The integrated circuit chip 400 is compressed in an operation in which the integrated circuit chip 400 is bonded to the pad portion PP2. In this case, the long edge portion of the bump electrode 450 may be cracked. The exemplary embodiments provide a structure of electrode pads EP capable of preventing crack expansion to the short edge portion.

While the inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

What is claimed is:

1. An integrated circuit chip comprising:
a substrate;
a terminal electrode disposed on the substrate; and
an electrode pad disposed on the terminal electrode,
wherein the electrode pad includes:
a bump structure protruded from the substrate to include a short side and a long side; and
a bump electrode disposed on the bump structure and connected with the terminal electrode around a short edge portion of the bump structure,
wherein the bump electrode is disposed to not cover at least a part of a long edge portion of the bump structure.

2. The integrated circuit chip of claim 1, wherein the bump electrode is disposed to not cover the long edge portion that is adjacent to the short edge portion of the bump structure.

3. The integrated circuit chip of claim 2, wherein the bump structure has a planar shape that is substantially rectangular and a short-side directional cross-section that is substantially semi-circular.

4. The integrated circuit chip of claim 2, further comprising an insulating layer disposed between the terminal electrode and the electrode pad, wherein the bump structure does not contact the terminal electrode.

5. The integrated circuit chip of claim 4, wherein the bump electrode has a portion that contacts the insulating layer at opposite sides of the bump structure in a long-side direction of the bump structure.

6. The integrated circuit chip of claim 2, further comprising
an insulating layer disposed between the terminal electrode and the electrode pad,
wherein the bump structure contacts the terminal electrode.

7. The integrated circuit chip of claim 6, wherein the bump electrode has a portion that contacts the terminal electrode at opposite sides of the bump structure in a long-side direction of the bump structure.

8. The integrated circuit chip of claim 6, wherein the bump structure is integrally formed with the insulating layer.

9. The integrated circuit chip of claim 1, wherein the bump structure is overlapped with the terminal electrode, and
a planar surface area of the terminal electrode is wider than that of the bump structure.

10. The integrated circuit chip of claim 1, wherein the bump electrode is disposed to not entirely cover the long edge portion of the bump structure.

11. A display device comprising:
a display panel including a pad portion; and
an integrated circuit chip bonded to the pad portion,
wherein the integrated circuit chip includes:
a substrate;
a terminal electrode disposed on the substrate; and
an electrode pad disposed on the terminal electrode,
wherein the electrode pad includes:
a bump structure protruded from the substrate to include a short side and a long side; and
a bump electrode disposed on the bump structure and connected with the terminal electrode around a short edge portion of the bump structure,
wherein the bump electrode is disposed to not cover at least a part of a long edge portion of the bump structure.

12. The display device of claim 11, wherein the bump electrode is disposed to not cover the long edge portion that is adjacent to the short edge portion of the bump structure.

13. The display device of claim 12, wherein the bump structure has a planar shape that is substantially rectangular and a short-side directional cross-section that is substantially semi-circular.

14. The display device of claim 12, wherein the integrated circuit chip further includes an insulating layer disposed between the terminal electrode and the electrode pad,
wherein the bump structure does not contact the terminal electrode.

15. The display device of claim 14, wherein the bump electrode has a portion that contacts the insulating layer at opposite sides of the bump structure in a long-side direction of the bump structure.

16. The display device of claim 12, wherein the integrated circuit chip further includes an insulating layer disposed between the terminal electrode and the electrode pad,
wherein the bump structure contacts the terminal electrode.

17. The display device of claim 16, wherein the bump electrode has a portion that contacts the terminal electrode at opposite sides of the bump structure in a long-side direction of the bump structure.

18. The display device of claim 16, wherein the bump structure is integrally disposed with the insulating layer.

19. The display device of claim 11, wherein the bump structure is overlapped with the terminal electrode, and
a planar surface area of the terminal electrode is wider than that of the bump structure.

20. The display device of claim 11, wherein the bump electrode is disposed to not entirely cover the long edge portion of the bump structure.
